(19) United States
(12) Patent Application Publication
(10) Pub. No.: US 2011/0062468 A1
(43) Pub. Date: Mar. 17, 2011

(54) PHOSPHOR-CONVERTED LIGHT EMITTING DIODE DEVICE

(75) Inventor: Mark M. BUTTERWORTH, Santa Clara, CA (US)

(73) Assignees: KONINKLIJKE PHILIPS ELECTRONICS N.V., EINDHOVEN (NL); PHILIPS LUMILEDS LIGHTING COMPANY, LLC, San Jose, CA (US)

(21) Appl. No.: 12/558,078

(22) Filed: Sep. 11, 2009

(51) Int. Cl. H01L 33/00; H01L 21/66

(52) U.S. Cl. 257/98; 438/14; 257/E33.067; 257/E33.061; 257/E21.529

(57) ABSTRACT

A light emitting diode is provided which is capable of emitting a first light having a first peak wavelength. The light emitting diode is provided with a phosphor layer overlying the light emitting diode and capable of absorbing the first light and emitting a second light having a second peak wavelength. The phosphor layer includes a pattern of holes positioned to allow the first peak wavelength to exit through the holes without being absorbed by the phosphor layer, and wherein the holes are placed to facilitate more of the first peak wavelength to exit the phosphor in the area of the holes than the second peak wavelength.

The present invention in general relates to light emitting diodes (LEDs) and, more particularly, to phosphor-converted LED devices that utilize phosphor to convert a primary light emitted by the LED into one or more other frequencies of light in order to generate white light.

With the development of efficient LEDs that emit blue or ultraviolet (UV) light, it has become feasible to produce LEDs that generate white light through phosphor conversion of a portion of the primary emission of the LED to longer wavelengths. Conversion of primary emission of the LED to longer wavelengths is commonly referred to as down conversion of the primary emission. An unconverted portion of the primary emission combines with the light of longer wavelength to produce white light. LEDs that produce white light are useful for signaling and/or other illumination purposes. U.S. Pat. No. 7,183,577 describes an example of a phosphor converted LED, hereby incorporated by reference.

There are many different ways to apply the phosphor to the LED including, but not limited to, placing the phosphor in an epoxy that is used to fill a reflector cup in which an LED sits. The phosphor is in the form of a powder that is mixed with the epoxy prior to curing the epoxy. The uncured epoxy slurry containing the phosphor powder is then deposited onto the LED and is subsequently cured. Similarly the phosphor powder can be combined with silicon to create a slurry, which is used to create a phosphor layer on the LED. There is also the static charge method in which the LED is charged and the phosphor powder statically attaches to the LED. A more recent way to apply phosphor to an LED is to use a ceramic phosphor plate that attaches to the LED. In all of these phosphor applications, particles within the phosphor are typically randomly oriented and interspersed throughout the medium holding the phosphor.

A popular phosphor to use with a blue LED is a YAG:Ce phosphor (Yttrium, Aluminum, Garnet doped with about 2% Cerium). We will refer to the YAG type of Phosphor in many of the examples, but it is understood that nothing in the application is limited to the use of the YAG type of phosphor. YAG is in the form of a cubic crystal with eight atoms in a cube. One atom is an Yttrium atom. The YAG is doped with Cerium (i.e. 2%) which means 2% of the Yttrium is replaced with Cerium. A property of Cerium is that it absorbs blue photons. The blue photons emitted by an LED if it impinges upon a Cerium atom push an electron of the Cerium atom into a higher orbital. As the electron falls back down it emits a photon typically of a yellow-green wavelength. The combination of the blue light emitted from the LED and the yellow-green light emitted from the phosphor creates a white light.

The random interspersion of the phosphor particles throughout any of the mediums means some of the blue light emitted from the LED impinges upon a phosphor particle and some does not. The result is that some unconverted blue light is emitted from the phosphor along with some converted yellow-green light. The combination of the blue light and yellow-green light creates white light. Due to the non-uniformity of the phosphor, this means that the blue light rays that travel a farther distance inside the phosphor layer are more likely to get converted than those light waves that have a shorter path. It is therefore difficult to control the ratio of blue light to converted light resulting in LED light output being non-uniform and typically having too much blue in the center, where the mean free path through the phosphor is typically shorter. It also results in too much yellow light at the edges where the mean free path is longer.

Accordingly, a need exists for a phosphor-converted LED that overcomes these problems and disadvantages.

The present invention preserves the advantages of prior art LEDs, and also provides new advantages not found in currently available LEDs. The current invention maximizes the output of a selected wavelength of light from the LED by limiting its exposure to the phosphor. This is performed by providing holes in the phosphor in the areas where it is desired to have more light which does not impinge with the phosphor, and less of the light which resulted from the impingement with the phosphor. The holes are therefore placed in the phosphor in a desired pattern which facilitates the emission of a desired wavelength of light.

In accordance with a preferred embodiment of the invention, a light emitting diode capable of emitting uniform white light is created by adding holes into the phosphor to allow blue light to exit unconverted in the areas where there is too much yellow-green light.

In another preferred embodiment of the invention the holes are angled allowing an adjustment of the radiation of the LED. In this way in areas where the mean free path of the blue light is longer, some of the blue light can freely exit through the holes reducing the amount of yellow green light in those areas.

In a further preferred embodiment of the invention, the hole diameters are varied to allow more blue light to exit.

In another aspect of a preferred embodiment of the invention, the light emitted from the LED is analyzed to determine the areas where hole placement will provide a better overall perceived color of the LED. This can be done visually, by taking a photo, or by using a spectrophotometer or some other means for measuring wavelength or determining color.

The placement of the holes in the preferred embodiment may be implemented using a laser, by molding, or by drilling etc.

It is therefore an object of the invention to provide an LED with a pattern of holes placed in the phosphor to allow for the exit of a preferred wavelength of light.

It is another object of the invention to provide an LED which has variable width holes to allow for the exit of a preferred wavelength of light.

It is a further object of the invention to provide an improved white LED by increasing the amount of holes at the edges of the LED where the mean free path of the light is typically longest.

It is even another object of the invention to provide hole patterns for various structure of an LED.

It is yet another object of the invention to provide a method of detecting the current light output of the LED and placing holes in the phosphor in the areas where there is too much of the wavelength of light which results form impingement of the phosphor.

Other objects and advantages will be apparent from the specification, drawings and claims.

For a fuller understanding of the invention, reference is made to the following drawings:

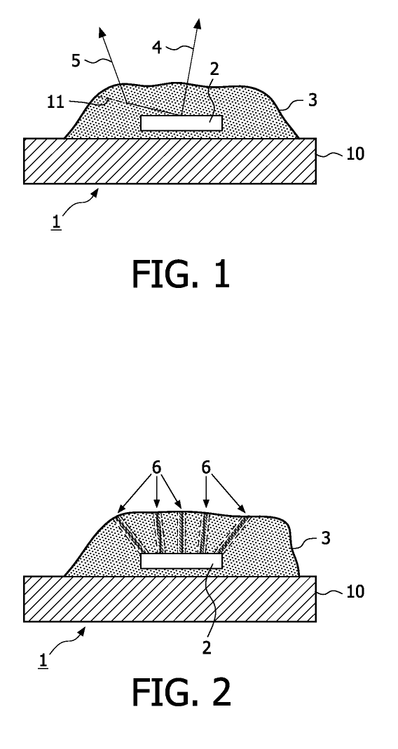

FIG. 1 shows an LED in accordance with the prior art, in which the blue and yellow-green light rays are emitted in accordance with the random impingement with phosphor particles.

FIG. 2. Shows an LED with the additional of holes in the areas where it is desirable to have additional unconverted blue light exit from the phosphor.

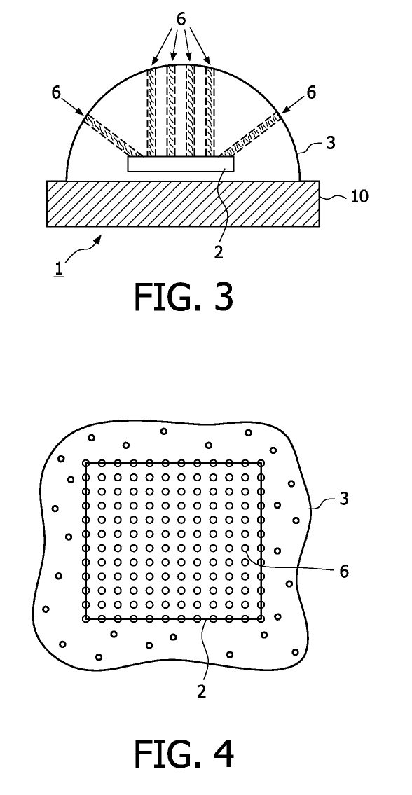

FIG. 3 shows another LED with the addition of holes through a dome shaped phosphor medium.

FIG. 4 shows a top view of an LED structure.

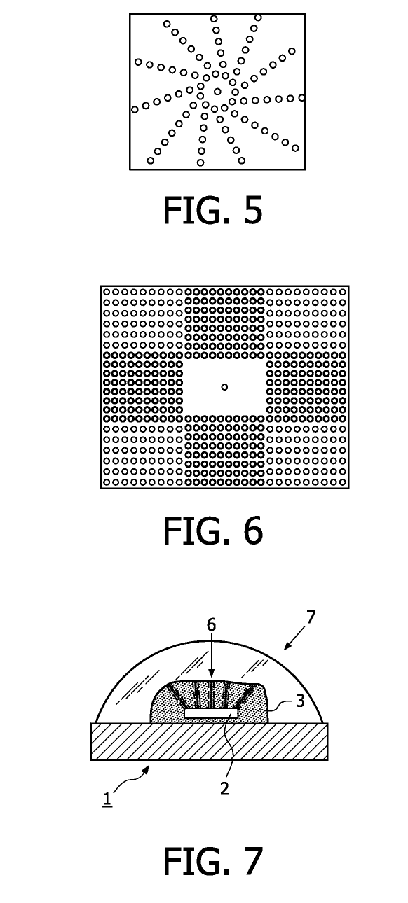

FIG. 5 shows one example of a hole pattern.

FIG. 6 shows another example of a hole pattern that compensates for excessive blue in the center (fewer holes) and excessive yellow-green at the edges (more holes).

FIG. 7 shows an LED in accordance with an embodiment of the invention included within a clear encapsulation lens of an LED assembly.

FIG. 1 is a perspective view of a phosphor coated LED 1 in accordance with the prior art. In this LED, a substrate is shown as 10. An LED 2 is typically grown or placed on the substrate 10, which is preferably sapphire, although other materials may be used for creating the light emitting diode 2 and the invention is not limited to the materials described herein. The LED 2 may, for example, be composed of two n-GaN layers, a GaInN layer, a p-AlGaN layer and a p-GaN layer. U.S. Pat. No. 7,183,577, assigned to the assignee of the current invention, describes an LED structure, as well as it being known to those skilled in the art. It should be noted that the LED of the present invention is not limited to any particular type or structure. Those skilled in the art will understand that a variety of known LEDs are suitable for use with the present invention. For the purpose of describing the invention, the LED will be shown as the structure 2 in the drawings.

A phosphor layer 3 is applied over the LED 2. The phosphor powder preferably is a Cerium-doped Yttrium-Aluminum-Garnet, also denoted as YAG:Ce. Those skilled in the art will also understand that the present invention is not limited to using any particular type of phosphor. Those skilled in the art will understand that other types of phosphors exist that are suitable for this purpose.

During operation, the light emitting structure 2 generates primary blue unconverted radiation 4 which is emitted when it passes through the phosphor 3 without exciting the dopants in the phosphor. It also generates yellow-green radiation 5 which is formed when a primary blue radiation is absorbed by the dopant, causing an electron in the dopant to raise an energy level and subsequently fall which emits a yellow-green light. The total amount of dopant in the phosphor is determined by its dopant concentration and by the thickness of the phosphor. The spatial distribution of the dopants in the phosphor can be controlled with some precision. The techniques used for this purpose are common to those skilled in the art. Those skilled in the art will also understand the manner in which the amount of light-emitting dopants in the phosphor and the spatial distribution of the dopants can be somewhat controlled.

It should be noted that the primary light may comprise light having more than one wavelength. Similarly, the light emitted in response to excitation by the primary light may comprise light of more than one wavelength. For example the blue light emitted by phosphor 3 may correspond to a plurality of wavelengths making up a spectral band. Wavelengths in this spectral band may then combine with the unconverted primary light to produce white light. Therefore although individual wavelengths are discussed herein for purposes of explaining the concepts of the present invention, it will be understood that the excitation being discussed herein may result in a plurality of wavelengths, or a spectral band, being emitted. Wavelengths of the spectral bands may then combine to produce white light. Therefore the term “spectral band” is intended to denote a band of at least one wavelength and of potentially many wavelengths, and the term “wavelength” is intended to denote the wavelength of the peak intensity of a spectral band.

As can be seen from FIG. 1 the paths the light rays 4 and 5 take either increase or decrease the probability of the light ray impinging upon a Cerium atom. The typical thickness of the phosphor is on the order of 50 microns-250 microns. The greater the phosphor thickness that the light must pass through, results in a greater probability that the light will impinge upon a Cerium atom. As can be seen from ray 5, it is directed off in an angle from LED 2. The distance between the start of the ray from the LED 2 and its exit out of the phosphor 3 shown by dashed line 11 is greater than the distance ray 4 must travel before it exits the phosphor 3. It is therefore more likely that ray 4 will be a blue ray and ray 5 will be a yellow-green ray. The result of this structure is that typically the rays that travel perpendicular to the LED tend to be blue rays and the rays that travel at an angle tend to be more of the yellow-green rays. This results in an LED with more blue color in the center of the light and more of a yellow-green tinge at the edges.

FIG. 2 shows a preferred embodiment of the instant invention. In FIG. 2, holes 6 are made in the phosphor 3. These holes 6 allow more blue light to exit without impinging on the phosphor atoms. These holes can be placed anywhere in the phosphor 3 where the production of excessive yellow-green light is causing a less than optimal white output. These holes 6 can be made by various methods such as laser ablation, drilling, molding etc. The correct amount of holes 6 and their associated pattern can be pre-calculated or done in-sitsu with a monitoring system such as a color meter or spectrophotometer.

In a preferred embodiment of the invention the positioning and diameter of the holes can be performed after analyzing, perhaps at various angles, the color change of the LED. When one looks at an LED from various angles the eye may see different colors, for example, the eye may see blue if looking directly perpendicular to the LED and yellow along the edges of the LED. One method which can be used to determine strategic hole placement is to simply shine an LED against a wall and take some type of photo of it to determine where there is too much yellow-green light. Typically the eye will see the blue in the center and yellow at the sides. Another method is to use a goniometer attached to a spectrophotometer. The spectrophotometer is moved over the LED and it measures the photons emitted from the LED and gives a reading of the intensity vs. wavelength of the photons. These measurements can be used to determine hole placement. An alternative method is to use a colorimeter to measure the x-y-z coordinate of the different colors. A colorimeter divides the light into red green and blue and looks at the ratio of the red, green and blue to determine what combined color is being emitted in a certain area. Once these measurements are taken, the proper placement and/or diameter of holes can be determined.

FIG. 3 shows an LED structure with a phosphor layer 3 that is thicker at the center. As can be seen by this figure, a light ray travelling directly perpendicular to the LED 2 may have a longer path to travel than a light ray traveling at an angle to the LED 2. In such a case more holes 6 may be needed towards the center of the LED to compensate for the higher probability of impingement on a Cerium atom. By strategically placing the holes in the phosphor, the color of the light can be improved at the precise points where it is needed. It should also be noted that the size of the holes can be varied to allow more or less unconverted light through the phosphor in certain areas.

FIG. 4 shows a top view of the LED structure in accordance with one embodiment of the invention. In this embodiment holes are placed in a matrix format across the LED in the center of the phosphor to allow more blue light through the center. The sides of the phosphor have less holes which may be due to the fact that the phosphor is thicker in the center.

FIG. 5 shows another pattern of holes in a top view of an LED structure. This pattern is intended to resolve the situation where more blue light is needed from the center of an LED and less is needed along the sides.

FIG. 6 shows another pattern of holes in a top view of an LED structure. In this pattern, there I less blue light needed from the center and more blue light needed at the sides of the phosphor. This would typically be used in a situation where the phosphor is in more of a thin film shape rather than a phosphor which is thicker in the middle than on the sides.

FIG. 7 shows a preferred embodiment of the invention encapsulated within a clear lens 7.

It will be understood by those skilled in the art that the present invention has been described with reference to particular embodiments, but that the present invention is not limited to these embodiments. Those skilled in the art will understand that various modifications may be made to the embodiments discussed above, which are within the scope of the present invention. As stated above, the present invention is not limited with respect to the materials used in the LED device. Those skilled in the art will also understand that, unless expressly stated herein, the present invention is not limited with respect to the order in which the layers or components of the LED device are formed. It will also be understood by those skilled in the art that the geometric arrangement or configuration of the phosphor is not limited to any particular arrangement.

For example, rather than using a single phosphor in the manner described above, a plurality of phosphor thin film segments, each which luminesces a different color of light in response to blue or ultraviolet primary radiation impinging thereon, may be deposited on a common surface. For example different configurations of thin film segments may be placed on the phosphor for example in a checker board fashion. Depending on the light color being emitted from each segment, hole placement may differ on each segment. Those skilled in the art will understand how various other configurations of phosphor layers and segments could be incorporated into an LED with strategic hole placement to optimize the color of the light.

Furthermore it should be noted that it is not required that white light be produced by the LED devices of the present invention. Those skilled in the art will understand the manner in which a phosphor can be produced and utilized in accordance with the principles of the present invention to obtain an LED device that produces other colors of light. For example, those skilled in the art will understand, in view of the description provided herein, how a phosphor may be obtained that produces green light by totally absorbing the blue or UV primary emission.

It would be appreciated by those skilled in the art that various changes and modifications can be made to the illustrated embodiments without departing from the spirit of the present invention. All such modifications and changes are intended to be covered by the appended claims.

1. A device comprising:
a light emitting diode capable of emitting at least one first light having a first peak wavelength;
a phosphor layer overlying the light emitting diode and capable of absorbing the first light and emitting at least one second light having a second peak wavelength; and
wherein the phosphor layer includes a pattern of holes positioned to allow the first peak wavelength to exit through the holes without being absorbed by the phosphor layer, and
wherein the holes are placed to facilitate more of the first peak wavelength to exit the phosphor in the area of the holes than the second peak wavelength.

2. The device of claim 1 wherein the phosphor comprises phosphor powder bound in an epoxy.

3. The device of claim 1 wherein the phosphor comprises a phosphor powder combined with silicon in slurry.

4. The device of claim 1 wherein the phosphor includes phosphor particles statically coupled to the LED.

5. The device of claim 1, wherein the phosphor is a phosphor ceramic plate.

6. The device of claim 1, wherein the holes are generated using a laser.

7. The device of claim 1, wherein the holes are generated by drilling.

8. The device of claim 1, wherein the holes are generated during molding.

9. The device of claim 1, where the pattern includes more holes along the sides of the LED than in the center of the LED.

10. The device of claim 1, wherein the phosphor is thicker in the center of the LED and the pattern includes more holes in the center of the LED than along the sides of the LED.

11. The device of claim 1, wherein the holes include a diameter and the diameter is varied depending on the amount of first light desired in a particular area.

12. The device of claim 1, wherein the strategic placement of the holes is determined by the results of a spectrophotometer.

13. The device of claim 1, wherein the strategic placement of the holes is determined by the results of a colorimeter.

14. The device of claim 1, wherein the strategic placement of the holes is determined by a photo of the light output.

15. A device comprising:
a light emitting diode capable of emitting at least one first light having a first peak wavelength;
a phosphor layer overlying the light emitting diode and capable of absorbing the first light and emitting at least one second light having a second peak wavelength; and
wherein the phosphor layer includes a pattern of holes to allow the first light having the first peak wavelength to exit through the holes without being absorbed by the phosphor layer, and wherein the holes have a diameter and the diameter and placement of the holes are placed and sized to increase the amount of the first light having a first peak wavelength which exits the phosphor through the holes.

16. A method comprising:
analyzing the color of light emitted from a light emitting diode, which includes a phosphor which is capable of i) absorbing a first light from the light emitting diode having a first wavelength and ii) emitting at least one second light having a second peak wavelength;
calculating from the analyzing step the amount of first light and second light exiting the phosphor across at least a portion of the phosphor;
placing holes in the phosphor to increase the amount of the first light having a first wavelength which exits the phosphor by allowing the light to pass through the holes instead of being absorbed by the phosphor.

17. The method in accordance with claim 16, wherein the holes have varying diameters in dependence on the result of the calculation step.

18. The method in accordance with claim 16, wherein the step of analyzing includes using a spectrophotometer to measure the light output across the light emitting diode.

19. The method in accordance with claim 16, wherein the step of analyzing includes using a colorimeter to measure the x-y-z coordinates of the light across the light emitting diode.
